(19) United States
(12) Patent Application Publication
(10) Pub. No.: US 2025/0259291 A1
(43) Pub. Date: Aug. 14, 2025

(54) SYSTEMS, METHODS, AND SOFTWARE FOR MULTILAYER METROLOGY

(71) Applicant: ASML NETHERLANDS B.V., Veldhoven (NL)

(72) Inventor: Jiyou FU, San Jose, CA (US)

(73) Assignee: ASML NETHERLANDS B.V., Veldhoven (NL)

(21) Appl. No.: 18/857,065

(22) PCT Filed: Apr. 18, 2023
(86) PCT No.: PCT/EP2023/060040

§ 371 Date: Oct. 15, 2024

Related U.S. Application Data
(60) Provisional application No. 63/338,129, filed on May 4, 2022.

(51) Int. Cl. G06T 7/00; G01N 23/2251

(52) U.S. Cl. CPC G06T 7/0004; G01N 23/2251; G01N 2223/401; G01N 2223/50; G01N 2223/6116; G06T 2207/10061; G06T 2207/20224; G06T 2207/30148

(57) ABSTRACT

Methods, apparatuses, and software are disclosed for multilayer metrology. One method includes obtaining image data of an object with an SEM system, with the image data acquired at multiple landing energy levels. A composed image is generated by performing pixel-by-pixel image processing of the image data. A metrology characteristic is determined from the composed image and metrology is performed on a feature based on the metrology characteristic.

### CROSS-REFERENCE TO RELATED APPLICATIONS

This application claims priority of U.S. application 63/338,129 which was filed on May 4, 2022 and which is incorporated herein in its entirety by reference.

### TECHNICAL FIELD

The description herein relates generally to metrology processes. More particularly, the disclosure includes apparatus, methods, and computer programs for performing multilayer metrology with one or more types of detectors in electron-beam systems.

### BACKGROUND

Objects manufactured with lithographic processes can be measured for quality assurance, developing improved manufacturing processes, etc. As one example, the overlay error between process layers can be measured. Various apparatuses can be utilized for measurement, including scanning electron microscopes.

### SUMMARY

Methods, apparatuses, and software are disclosed for multilayer metrology. In one aspect, a method includes obtaining image data of an object with an SEM system, the image data acquired at multiple landing energy levels; generating a composed image by performing pixel-by-pixel image processing of the image data; determining a metrology characteristic from the composed image; and performing metrology on the feature based on the metrology characteristic.

In some variations, the feature can be manufactured on a wafer through a semiconductor manufacturing process and the feature can include a contact hole, a short bar, a line, a tilted bar, a bit line, or an active area. The multiple landing energy levels can be selected to obtain the image data from selected depth levels within the object. The metrology characteristic can be a side wall angle of the feature, a CD for OPC metrology, a LER for SEPE metrology, an EPE for EPE metrology, or an overlay for overlay metrology.

In other variations, the SEM system can include one or more BSE detectors that obtain first image data at a first landing energy and second image data at a second landing energy, the first landing energy being higher than the second landing energy. The composed image can be generated by subtracting the second image data from the first image data.

In yet other variations, the SEM system can include a BSE detector and an EF detector, the BSE detector obtaining first image data at a first landing energy and the EF detector obtaining second image data at a second landing energy. The composed image can be generated by subtracting the second image data from the first image data.

In some variations, the SEM system can include a BSE detector, an EF detector, and an SE detector, the BSE detector obtaining first image data at a first landing energy, the EF detector obtaining second image data at a second landing energy, and the SE detector obtaining third image data at a third landing energy. The composed image can be generated by subtracting the second image data and the third image data from the first image data.

In other variations, the composed image can be generated from function5(function1(BSE_1), function2(BSE_2), function3(SE), funcation4(EF)), where function1, function2, function 3, and function 4 are image pre-processing functions and function5 is a mathematical function that combines the image data processed by the image pre-processing functions. The image pre-processing functions can be any combination of denoising functions or grey-level adjustments. The mathematical function can be linear or non-linear function, including an addition, a subtraction, multiplication, division, Fourier analysis, or a logarithmic operation.

In an interrelated aspect, a method includes obtaining image data from multiple depth levels of an object from a first detector and a second detector of an SEM system; obtaining a first design layout corresponding to a first process layer of the object; obtaining a second design layout corresponding to a second process layer of the object; aligning the image data from the first detector with the first design layout; aligning the image data from the second detector with the second design layout; and determine a metrology characteristic from the aligned first image data and the aligned second image data.

In some variations, first image data and the second image data can be from the same location on the object. Determining the metrology characteristic can include calculating an overlay between the aligned first image data and the aligned second image data. The first design layout and the second design layout can be comprised of GDS data. The first detector can be an SE detector that generates first image data and the second detector can be a BSE detector that generates second image data and the method can include generating third image data from an EF detector.

In other variations, the metrology characteristic can be a pattern shift between the first process layer and the second process layer. Determining the pattern shift can include determining a difference between a second location of the aligned second image data and a first location of the aligned first image data, the aligned second image data determined in part by subtracting the third image data from the second image data.

In an interrelated aspect, a method includes obtaining image data from multiple depth levels of an object from a first detector and a second detector of an SEM system; obtaining a design layout of the object; aligning the image data from the first detector with the design layout; determining a region of interest based on the aligned image data; and performing an image processing operation on the image data from the second detector in the region of interest.

In some variations, the image processing operation can include image quality enhancement, segmentation, contour extraction, template matching, or machine learning based feature recognition.

In an interrelated aspect, a method includes obtaining image data of multiple depth levels of an object from a first detector and a second detector of an SEM system, the image data from the second detector being from a buried process layer of the object and one or more process layers above the buried process layer; and determining a metrology characteristic of a feature of the object based on the image data.

In some variations, the metrology characteristic can be a side wall angle of the feature as determined from CDs as measured at the buried process layer and a second process layer and from a nominal thickness between the buried process layer and the second process layer, the side wall angle determined utilizing the first detector and the second detector or utilizing the first detector at different landing energies. The metrology characteristic can include LERs at multiple depth levels of the object or EPEs at multiple depth levels of the object. The first detector can be an SE detector that generates first image data and the second detector can be a BSE detector that generates second image data from the buried process layer.

In an interrelated aspect, a method includes obtaining image data of multiple process layers of an object from detectors of an SEM system, the image data acquired at multiple landing energy levels for each of the plurality of detectors; and determining, from the image data of the multiple process layers, a combination of detectors and landing energies, current, scanning speed, pixel size and field of view size that result in a measured overlay being closest to directly proportional to a target overlay.

In some variations, the method can include setting, for the combination of detectors, the respective landing energies and other SEM parameters; and performing metrology utilizing the combination of detectors having the respective landing energies. The detectors can include an SE detector and a BSE detector. The detectors can include an EF detector, the method including scanning multiple energy filter levels when obtaining the image data, where the combination also includes an energy filter level of the multiple energy filter levels.

In other variations, the method can include generating composed images by combining at least a portion of the image data obtained by the scanning, the determining of the combination based on the combined image data.

In an interrelated aspect, a method includes obtaining image data at a plurality of process layers with an SEM system having a plurality of detectors utilizing a plurality of landing energy levels; generating a plurality of metrology characteristics for a plurality of process layers from the image data; determining a difference between two of the plurality of process layers based on the plurality of metrology characteristics; and providing an indication when the difference exceeds a difference threshold.

In some variations, the metrology characteristics can be pattern locations and the difference can be an overlay between a first pattern location on a first process layer and a second pattern location on a second process layer. The metrology characteristics can be CDs for OPC metrology and the difference can be a CD difference between a first process layer and a second process layer, the metrology characteristics can be LERs for SEPE metrology and the difference can be an LER difference between a first process layer and a second process layer, or the metrology characteristics can be EPEs for EPE metrology and the difference can be an EPE difference between a first process layer and a second process layer.

In other variations, the detectors can include an SE detector and a BSE detector. The detectors can also include an EF detector, the method further comprising obtaining the image data utilizing the EF detector at a number of energy filter levels.

In some embodiments, there can be a non-transitory computer readable medium having instructions recorded thereon for performing multilayer metrology, the instructions when executed by a computer having at least one programmable processor cause operations comprising any of the operations in the above method embodiments.

In some embodiments, there can be a system for performing multilayer metrology, the system comprising: at least one programmable processor; and a non-transitory computer readable medium having instructions recorded thereon, the instructions when executed by a computer having the at least one programmable processor cause operations comprising any of the operations in the above method embodiments.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 is a schematic diagram of an exemplary scanning electron microscope system, according to an embodiment of the present disclosure.

FIG. 2 is a diagram of an exemplary object containing numerous process layers, according to an embodiment of the present disclosure.

FIG. 3 is a diagram illustrating generating of a composed image for metrology of buried process layer features, according to an embodiment of the present disclosure.

FIG. 4 is a diagram illustrating an example of performing metrology that includes aligning image data to design layouts, according to an embodiment of the present disclosure.

FIG. 5 is a diagram illustrating an example of improving imaging of a buried process layer utilizing aligned images, according to an embodiment of the present disclosure.

FIG. 6 is a diagram illustrating an example of utilizing multiple detectors to perform metrology involving a buried process layer, according to an embodiment of the present disclosure.

FIG. 7 is a diagram illustrating determining a combination of detectors and landing energies for determining an overlay, according to an embodiment of the present disclosure.

FIG. 8 is a diagram illustrating diagnosing an object by determining overlays at multiple process layers, according to an embodiment of the present disclosure.

FIG. 9 is a diagram illustrating diagnosing process errors by utilizing composed images based on different landing energies, according to an embodiment of the present disclosure.

FIG. 10 is a block diagram of an example computer system, according to an embodiment of the present disclosure.

### DETAILED DESCRIPTION

The manufacture of semiconductor devices involves many repetitions of processing to build up device structures with appropriate materials and patterns, layer-by-layer on a substrate by, for example, a lithography apparatus. Each layer of the product structure can utilize a different set of process steps, and the lithography apparatuses used at each layer may be completely different in type. Further, even where the processing steps to be applied by the apparatus are nominally the same, in a large facility, there may be several supposedly identical machines working in parallel to perform the processing steps on different substrates. Small differences in set-up or faults between these machines can mean that they influence different substrates in different ways. Even steps that are relatively common to each layer, such as etching may be implemented by several etching apparatuses that are nominally identical but working in parallel to maximize throughput. In practice, moreover, different layers may require different etch processes, for example chemical etches, plasma etches, according to the details of the material to be etched, and special requirements such as, for example, anisotropic etching.

The previous or subsequent processes may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore, some layers may be exposed in an immersion type lithography tool, while others are exposed in a ‘dry’ tool. Some layers may be exposed in a tool working at DUV wavelengths, while others are exposed using EUV wavelength radiation.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly, metrology systems can receive such substrates that have been processed. Metrology results can be provided directly or indirectly to a supervisory control system. If errors are detected, adjustments may be made to exposures of subsequent substrates, especially if the metrology can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

As used herein, the term “target pattern” means a pattern as designed that is to be fabricated on the wafer.

As used herein, the term “patterning process” means a process that creates an object by the application of various lithography processes.

As used herein, the term “process layer” refers to a region of the printed object (e.g., a semiconductor device) that was created with the patterning processes. Process layers can be made of the different materials or may be different regions that are processed (e.g., when performing an etch the area with material removed may be considered one process layer and the area below it without material removed may be considered another process layer).

As used herein, the term “depth level” refers generally to the distance from the surface of the object For example, the disclosed imaging methods can enable imaging at different depth levels (e.g., at different process layers) but can also include imaging at different depth levels within a single process layer.

As used herein, the term “printed pattern” means the physical pattern that was formed on the wafer. The printed pattern can include features, for example, vias, contact holes, troughs, channels, depressions, edges, or other two- and three-dimensional features resulting from a lithography process.

As used herein, the term “imaging device” means any number or combination of devices and associated computer hardware and software that can be configured to generate images of a target, such as the printed object or portions thereof. Non-limiting examples of an imaging devices can include: scanning electron microscopes (SEMs), x-ray machines, etc.

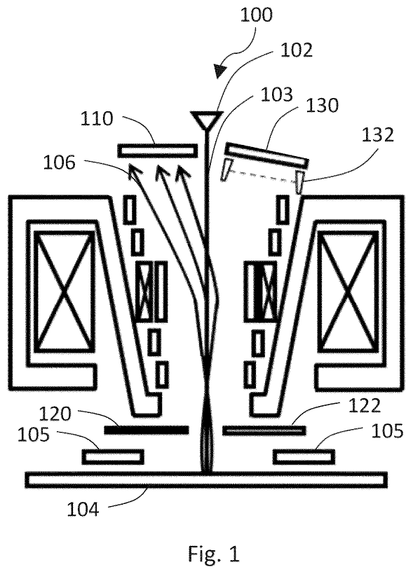

FIG. 1 is a schematic diagram of an exemplary scanning electron microscope system, according to an embodiment of the present disclosure.

SEM system 100 can include an electron source 102 that generates an electron beam 103 directed to an object 104 to be imaged. Electrons in electron beam 103 are typically generated with energies in the kilovolt (kV) range, for example, between 1-60 kV. High-voltage plates 105 can be included to control the energy with which the electrons in the electron beam 103 reach object 104, for example by having a retarding potential less than the initial energies of the emitted electrons (e.g., a retarding potential of 3 to 25 keV). The energy is which electrons then land at the object is referred to herein as the “landing energy.” Scattered electrons 106 emitted from object 104 can then be collected by various detectors of the SEM system 100. One detector that can be in any of the disclosed embodiments can include a scattered electron (SE) detector 110. Other detectors can include backscattered electrons (BSE) detectors such as BSE detectors 120 and 122. Yet another type of detector can be an energy filter (EF) detector 130, which may combine an SE detector and an energy filter 132. Energy filter 132 can be a mesh, plates, etc. that apply a retarding potential to repel scattered electrons below a certain energy such that they do not reach the SE detector. The retarding potential of energy filter 132 can be, for example, between 1 kV and 20 kV. Any of the embodiments described herein can include any combination of the disclosed detectors. In some systems, not all detectors need to be used with every disclosed method. For example, an SEM system could have all three of the above types of detectors present but may only use one or two of them in a particular application. Also, the retarding potentials described above are examples only and can be varied with the particular embodiment. In some embodiments, to facilitate imaging with multiple detectors, any position offset between any of the two detector images can be determined and the images and/or detectors can be calibrated such that the resultant images have aligned centers.

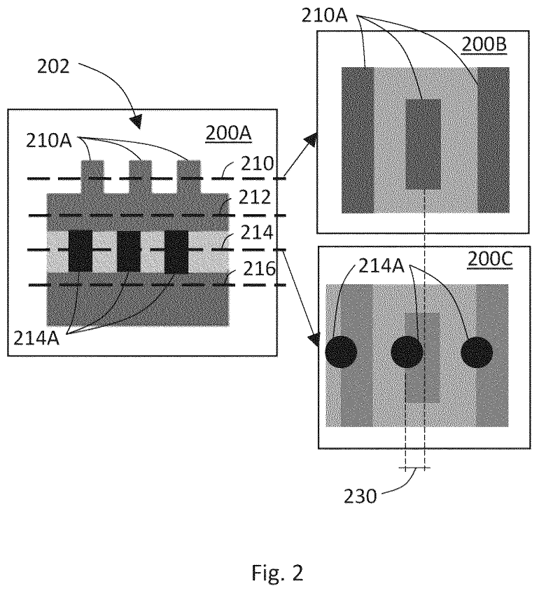

FIG. 2 is a diagram of an exemplary object containing numerous layers, according to an embodiment of the present disclosure.

Panel 200A shows a cross-sectional view of a portion of an object 202 (e.g., a printed integrated circuit). Object 202 can include one or more features (e.g., lines, bars, contact holes, etc.) that may be of particular interest in imaging, for example, for performing metrology thereon. For example, the feature can be manufactured on a wafer through a semiconductor manufacturing process and examples of features can include a contact hole, a short bar, a line, a tilted bar, a bit line, an active area, or in general can be any pattern described by a design layout (such as can be represented by GDS data of a pattern, circuit, etc.). As shown in panel 200A, the features can be on one or more process layers, for example, any of example process layers 210, 212, 214, and 216. Such process layers can be, for example, process layer 210 (e.g., a grating layer), 212 (e.g., a film layer), 214 (e.g., a via layer), and 216 (e.g., a substrate). As described further herein, controlling the SEM system to utilize different types of detectors, with electrons from the SEM having different landing energies, and in some cases utilizing variations in energy filter retarding potentials, can permit obtaining image data at specific selected layers.

As depicted in panel 200A, the dashed line showing the imaging plane in focus in layer 210 can include features such as bars 210A (e.g., material that had not been etched away) and the dashed line showing the imaging plane in focus in process layer 214 can include features such as contact holes 214A. Panels 200B and 200C depict imaging process layers 210 and 214 to illustrate an example of overlay 230 between the process layers. In some embodiments, such as for DRAM semiconductor devices, the overlay can be found as, for example, the shift between the bitline and the active area at a buried process layer, the overlay between a wordline and the active area, etc. In addition to determining overlays, such targeted imaging at a particular process layer can be used to measure the top CD of a storage capacitor, a line width and roughness of a bit line, etc.

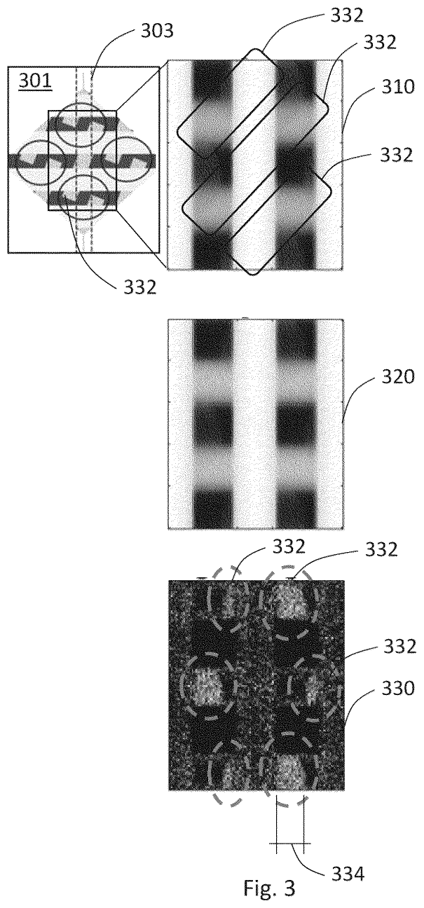

FIG. 3 is a diagram illustrating generating of a composed image for metrology of buried process layer features, according to an embodiment of the present disclosure.

The present disclosure provides various methods of performing metrology, particularly metrology of features at buried (including partially buried) process layers or at different depths within a process layer. While the aforementioned detectors can be configured to be more sensitive to scattered electrons from a particular process layer, it can still be challenging to obtain buried process layer information due to, for example, scattered electrons obtained from other depth levels in the object. Disclosed methods of performing metrology of a buried process layer can utilize image processing to bring out buried process layer information. For example, in one embodiment a method can include obtaining image data of an object with an SEM system, with the image data acquired at multiple landing energy levels. As described herein, such multiple landing energy levels can be selected to obtain the image data from selected depth levels within the object. As shown in FIG. 3, a design layout 301 depicts active areas tips 332 (light grey and diagonal) that can be in a buried process layer deeper in the object. To the right, there is an example of top process layer image data 310 of an object obtained by, for example, a BSE detector detecting the scattered electrons from the object when the SEM system is selected to operate at a particular landing energy (e.g., 20 keV). The locations of the buried active areas tips 332 are shown for reference though not discernable in the example image. Also, the portion of the active area tip in the center is obscured by the bitline 303. Buried process layer image data 320 can also include that from a BSE detector detecting the electrons having a higher landing energy level (e.g., 30 keV), which causes the scattered electrons to emanate from deeper in the object and thereby provide more information from a buried process layer. The buried process layer image data 320 appears almost identical to top process layer image data 310 due to the dominant contribution of scattered electrons from the top process layer, even though in the buried process layer image data 320 there is nevertheless an increase in contribution from scattered electrons at the buried process layer.

According to embodiments of the present disclosure, to obtain the buried process layer information, some methods can include generating a composed image 330 by performing pixel-by-pixel image processing of the image data. Composed image 330 shows examples (circled) of buried process layer information, in this case the active area tips 332 at the buried process layer. Examples of pixel-by-pixel image processing can include, for example, adding, subtracting, etc. of the pixel intensities or equivalent data representations of the image intensity. In FIG. 3, composed image 330 is generated by subtracting BSE image data 310 captured using 20 keV landing energy from BSE image data 320 captured using 30 keV landing energy. The resultant image data represented by composed image 330 thereby emphasizes the features at the buried process layer.

With composed image 330 more clearly depicting features at the buried process layer, such methods can also include determining a metrology characteristic from the composed image and performing metrology on the feature based on the metrology characteristic. Examples of metrology characteristics can include a side wall angle of the feature, a critical dimension (CD) for optical proximity correction (OPC) metrology, a line edge roughness (LER) for stochastic edge placement error (SEPE) metrology, an edge placement error (EPE) for EPE metrology, an overlay for overlay metrology, etc. In the example of FIG. 3, referring to a design layout 301, CDs (e.g., CD 334) can be determined for the active area tips 332 at the buried process layer. Accordingly, performing metrology by such methods can provide buried process layer information to characterize the features of interest, similar to that shown in the example of FIG. 2.

As previously mentioned, various embodiments can combine different detectors, landing energies, energy filters, etc. In one embodiment, the SEM system can include one or more BSE detectors that obtain first image data at a first landing energy and second image data at a second landing energy, the first landing energy (e.g., 30 keV) being higher than the second landing energy (e.g., 20 keV). The composed image can then be generated by subtracting the second image data from the first image data.

In another embodiment, the SEM system can include a BSE detector and an EF detector, the BSE detector obtaining first image data at a first landing energy (e.g., 20 keV) and the EF detector obtaining second image data at a second landing energy (e.g., at 30 keV and a retarding potential of the energy filter at 15 keV). The composed image can then be generated by subtracting the second image data from the first image data.

In yet another embodiment, the SEM system can include a BSE detector, an EF detector, and an SE detector, the BSE detector obtaining first image data at a first landing energy (e.g., 30 keV), the EF detector obtaining second image data at a second landing energy (e.g., at 20 keV and a retarding potential of the energy filter at 7 keV), and the SE detector obtaining third image data at a third landing energy (e.g., 15 keV). The composed image can be generated by subtracting the second image data and the third image data from the first image data.

Image processing software can implement a generalized function to process one or more groups of image data and generate composed images. One expression of such a generalized function can be: function5(function1(BSE_1), function2(BSE_2), function3(SE), funcation4(EF)), where function1, function2, function3, and function4 are image pre-processing functions and function5 is a mathematical function that combines the image data processed by the image pre-processing functions.

The image data processed by function5 can include image data from any combination of detectors, with one specific example provided above. The image pre-processing functions can be, for example, any combination of denoising functions or grey-level adjustments. The mathematical function can be a linear or non-linear function, for example, an addition, a subtraction, multiplication, division, Fourier analysis, or a logarithmic operation.

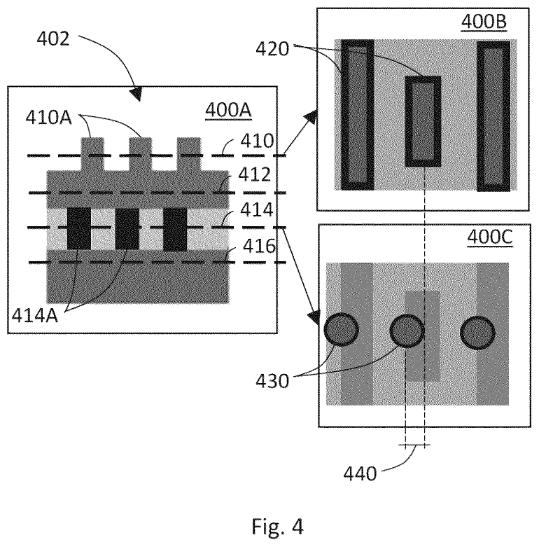

FIG. 4 is a diagram illustrating an example of performing metrology that includes aligning image data to design layouts, according to an embodiment of the present disclosure.

One important metrology characteristic that can be determined for an object is the overlay between any two process layers of interest. As used herein, the term “overlay” means a displacement between two process layers. For example, two process layers may be intended to have aligned centers (e.g., a top process layer directly over a lower process layer) but during manufacturing undesirably constructed with a shift between the two process layers (e.g., an offset (or overlay) in the X and/or Y directions). To more accurately calculate overlays, images can be aligned to GDS data (or otherwise known coordinates in the planned design) and then the overlay can be calculated based on the aligned images.

In one embodiment, a method can include obtaining image data from multiple depth levels of an object from a first detector and a second detector of an SEM system. In FIG. 4 this is depicted in 400A showing object 402 with an exemplary feature (e.g., bars 410A) imaged at a first process layer 410 (e.g., top process layer) and another feature (e.g., contact holes 414A) imaged at a second process layer 414.

The method can also include obtaining a first design layout 420 (e.g., GDS data) corresponding to the first process layer 410 with object 402 and obtaining a second design layout 430 corresponding to the second process layer 414 of object 402. Panel 400B depicts aligning the image data (e.g., including the top process layer 410 information) from the first detector with the first design layout 420. Panel 400C depicts aligning the image data (e.g., including the buried process layer information) from the second detector with the second design layout 430. In some embodiments, the alignment can be done with pattern matching, for example, based on a determined correlation between the image data and the design layout.

Panel 400C also depicts determining a metrology characteristic from the aligned first image data and the aligned second image data. In this example, determining the metrology characteristic can include calculating overlay 440 between the aligned first image data and the aligned second image data. The overlay can be calculated in the X direction and/or in the Y direction, with only the X direction shown in panel 400C. In other embodiments, different metrology characteristics can be determined, for example, by the side wall angle based on differences between measured edges of features in the aligned images.

In some embodiments, the first image data and the second image data can be from the same location on the object. However, in other embodiments, the first image data and the second image data can be at different locations in the object. For example, if two features are expected to be particular locations based on their respective design layouts, images can be obtained at those two different locations and then the overlay can be calculated taking into account expected differences in the locations. In other words, if a contact hole at a top process layer is at a position (X1,Y1) in the design layout, and a different contact hole at a buried process layer is at a position (X2, Y2), then the overlay can be determined from the aligned images, but subtracting the expected differences in locations (e.g., subtracting X2−X1 from the X overlay and Y2−Y1 from the Y overlay).

As another example embodiment, the first detector can be an SE detector that generates the first image data and the second detector can be a BSE detector that generates the second image data. Also, the method can include comprising generating third image data from an EF detector. Similar to the above, the metrology characteristic can be a pattern shift between the first process layer and the second process layer. In this embodiment, determining the pattern shift can include determining a difference between a second location of the aligned second image data and a first location of the aligned first image data, with the aligned second image data determined in part by subtracting the third image data from the second image data. Or, expressed mathematically in terms of image data sources, the pattern shift can be the location of image 1 (SE)-the location of image 2 (BSE-EF).

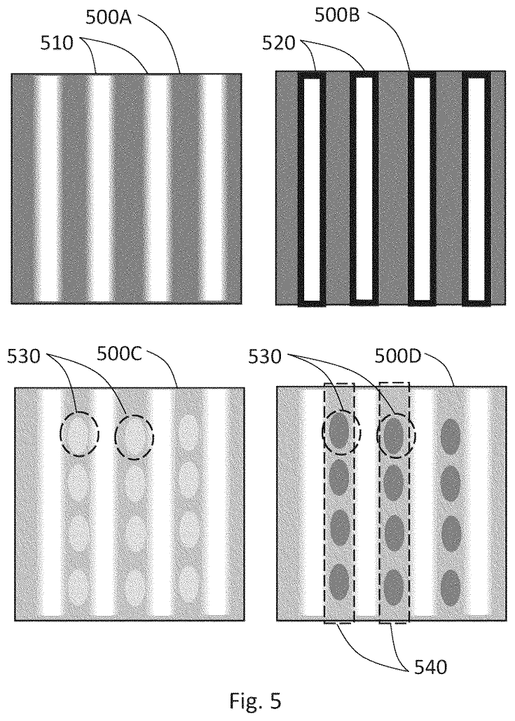

FIG. 5 is a diagram illustrating an example of improving imaging of a buried process layer utilizing aligned images, according to an embodiment of the present disclosure.

In some embodiments, various image processing operations can be performed based on buried process layer image data. For example, contouring or denoising may be desired around the region of a buried process layer contact hole to more clearly define or depict its features. Such image processing operations can benefit by processing a specific region of interest rather than an entire image field of view. Enhancing the contrast or sharpness of an image may provide very different results depending on what is in the image. For example, where a buried feature is blurry in an image but the image as a whole was quite sharp, such image processing operations may provide little benefit. However, by restricting processed region of interest to the blurry buried features, the image improvement to the buried features may be more substantial.

As depicted in FIG. 5, one embodiment that can provide such benefits can include obtaining image data from multiple depth levels of an object from a first detector and a second detector of an SEM system. For example, panel 500A depicts an image from the first detector (e.g., an SE detector) and panel 500C depicts an image from the second detector (e.g., a BSE detector). The image in panel 500A shows lines 510 but does not show deeper or buried process layer information. The image in panel 500C depicts the same features as in 500A, but with buried features 530 (shown circled)-and could benefit from further image processing as described herein. The method can also include obtaining a design layout 520 (e.g., GDS data) of the object. In this example, design layout 520 includes lines shown by rectangles that correspond to the bright lines 510 in 500A. The image data from the first detector can be aligned with the design layout as shown in 500B. Again, such alignment can be performed by, for example, aligning the SEM data to GDS data of the design layout.

Panel 500D depicts determining a region(s) of interest 540 based on the aligned image data. For example, the region of interest 540 may be selected to be the region between the lines 510 such that they focus on buried features 530 contained therein. Accordingly, such regions of interest can be selected based on the design layout, once the image and design layout are aligned. The depicted rectangular outlines representing the exemplary regions of interest are shown as examples only and slightly enlarged for illustrative purposes. The method can also include performing an image processing operation on the image data from the second detector in the region of interest. Examples of image processing operations can include image quality enhancement (e.g., image subtraction, denoising, contrast enhancement, sharpening, greyscale adjustments, etc.), segmentation, contour extraction, template matching, machine learning based feature recognition, etc. As seen in 500D, when image 500C is further processed the buried features are shown much more clearly.

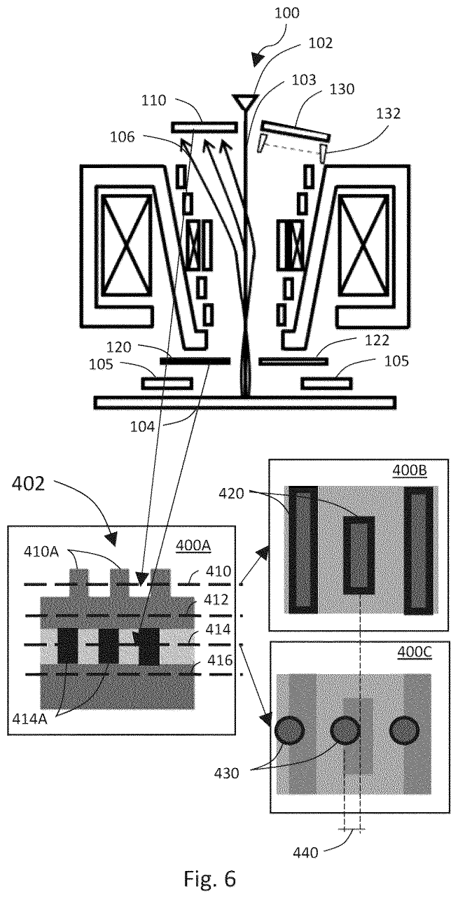

FIG. 6 is a diagram illustrating an example of utilizing multiple detectors to perform metrology involving a buried process layer, according to an embodiment of the present disclosure.

FIG. 6 depicts an SEM system 100 similar to that shown in FIG. 1, including SE detector 110, BSE detectors 120 and 122, and EF detector 130. FIG. 6 also depicts an example of utilizing image data from some of the detectors to determine a metrology characteristic (e.g., an overlay between a top process layer 410 and a buried process layer 414). The depicted method in FIG. 6 is similar to that described with reference to FIG. 4 (with some elements reproduced in FIG. 4 based on their similarity), but with FIG. 6 depicting utilizing at least two detectors (which may be the same type or different). While the example in FIG. 6 describes imaging at depth levels corresponding to different process layers (e.g., top process layer 410 and buried process layer 414), in general, the imaging can be from any two depth levels in the object, either in the same process layer or in different process layers.

The method depicted in FIG. 6 can include, for example, obtaining image data from multiple depth levels of an object 402 from a first detector and a second detector of an SEM system. As shown, the image data from the second detector can be from a buried process layer (e.g., 412, 414, or 416) of the object. As shown in the exemplary embodiment of FIG. 6, the first detector can be an SE detector 110 that generates first image data (e.g., from top process layer 410) and the second detector can be a BSE detector 120 or 122 that generates second image data from buried process layer 414. Also, in some embodiments, the first image data can be obtained from deeper in the object, e.g., at a buried process layer, for example by increasing the landing energy during imaging by the first detector. In this way, the present disclosure contemplates embodiments where two detectors can be utilized to image different process layers at any depth level in the object. Accordingly, one benefit of the disclosed multidetector system can be providing simultaneous imaging and/or performing metrology without having to rely on images taken at different times.

In other embodiments, the method can also include determining a metrology characteristic of a feature of the object based on the image data. For example, metrology characteristic can be a side wall angle of the feature. The side wall angle can be calculated as, for example, arctan (dx/T), where dx is the displacement between the edges of the sidewall as measured in the two imaged depth levels and T is the thickness or height difference between the depth levels. In some embodiments, the side wall angle of the feature can be determined from CDs as measured at the buried process layer and a second process layer and from a nominal thickness between the buried process layer and the second process layer. In some embodiments thickness can be calculated as the nominal thickness based on averaging over some distance or area to get an average height of such a surface process layer. This average height (or nominal thickness) can then be utilized in the side wall angle calculation. The side wall angle can be determined utilizing the first detector and the second detector or utilizing the first detector at different landing energies. As disclosed herein, different detector types can provide information at different depth levels. Similarly, utilizing different landing energies can also provide information at different depth levels. Other metrology characteristics that can be determined can include CDs at multiple depth levels of the object, LERs at multiple depth levels of the object, EPEs at multiple depth levels of the object, and an overlay between process layers of the object. For example, overlay 440 (for whichever two process layers are being imaged) can be determined in a manner similar to that described with reference to FIG. 4.

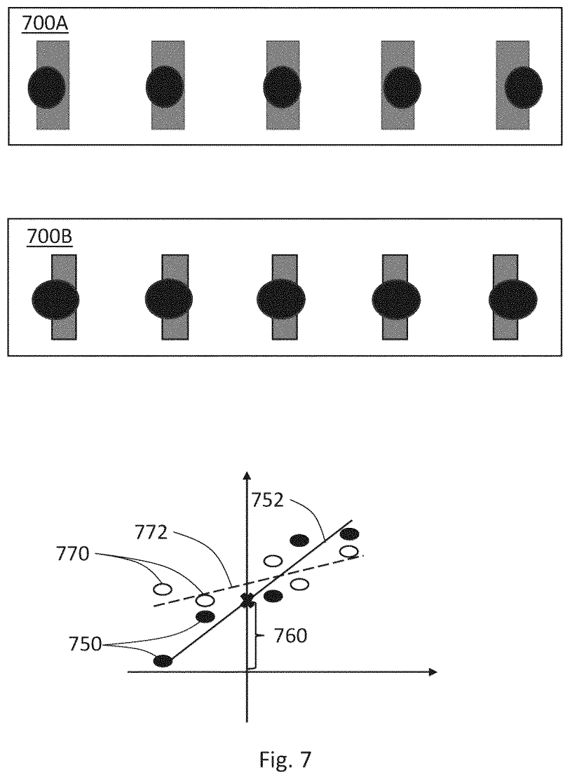

FIG. 7 is a diagram illustrating determining a combination of detectors and landing energies for determining an overlay, according to an embodiment of the present disclosure.

Images generated by the various detectors of the SEM system (e.g., SE, BSE, LE, etc.) may be different due to detector design and the utilized landing energies (e.g., 1-50 keV). Accordingly, it can be beneficial to determine which combination of detectors and respective landing energies will produce overlay calculations that are predominantly only a function of the actual overlay.

Panel 700A depicts simplified exemplary images of a contact hole and a short bar, such as could be imaged by, for example, an SE detector of an SEM system. The five images correspond to different expected (or set) overlays (e.g., the difference in position between the center of the contact hole and the location the short bar). The set overlays depicted can range from, for example, −5 to +5 nm, though any values of overlay can be implemented.

Panel 700B depicts a similar image set but acquired with a different detector (e.g., a BSE detector). Due to the differences in the images received when different detectors, landing energies, etc. are used, the measured overlays can have some variation. Thus, the present disclosure provides methods of determining the best combination of detectors and detector parameters (e.g., LE, EF level, etc.).

In one embodiment, a method can include obtaining image data of multiple process layers of an object from a number of detectors of an SEM system. The image data can be acquired at multiple landing energy levels for each of the detectors. The method can also include determining, from the image data of the multiple process layers, a combination of detectors and landing energies that result in a measured overlay being closest to directly proportional to a target overlay. This is depicted by the plot below panel 700B. The X-axis represents an overlay expected to be measured. The Y-axis represents the actual measured overlay. The data points 750 (solid ovals) and 770 (open ovals) represent measurements taken with two different combinations of detectors/landing energies. In this example, the first combination utilizes a first detector (e.g., an BSE detector) at an 18 keV landing energy and the second detector (e.g., an SE detector) utilizes a 5 keV landing energy. A linear fit 752 can be performed through data points 750 to obtain the slope and intercept 760. The desired combination is that which has slope closest to one and having a reasonable intercept (i.e., the measured overlay compared to the actual overlay). This is shown by the first combination. By “closest to one” this means that ideally it would be one, but in certain embodiments can be the closest to one given the provided data (e.g., if the best fit results in the slope of 0.98, such may be selected as being “closest to one.”). In other embodiments, the condition of being “closest to one” can include being within a specified range imprint e.g., −0.9 to 1.1. Reasonable intercepts can be specified by a user or the system to be within a particular range. For example, reasonable offsets may include any values between +5 nm, +1 nm, etc. As a counter example, the plot shows data points 970 from first detector at a 30 keV landing energy, a second detector at a 25 keV landing energy, and a corresponding linear fit 772 through those data points. As seen, the slope of linear fit 772 is not closest to one and therefore that combination of detectors and landing energies may not be selected.

In some embodiments, various methods can also include setting, for the combination of detectors, the respective landing energies and other SEM parameters (e.g., field of view, accelerating voltage, etc.) and performing metrology utilizing the combination of detectors having the respective landing energies.

As with any of the embodiments disclosed herein, any of the disclosed detector types can be utilized in any combination. As one example, the detectors can include an SE detector and/or a BSE detector, with varying landing energy settings.

In some embodiments, the detectors can include an EF detector, where the method may also include scanning multiple energy filter levels when obtaining the image data. The selected combination of detectors and settings may then also include an energy filter level of the scanned multiple energy filter levels. Another way in which certain embodiments can benefit from aspects of the present disclosure is that determining measured overlays can include generating composed images by combining at least a portion of the image data obtained by the scanning. Then, various embodiments can include determining the combination based on the combined image data and/or the composed images used to determine the overlays.

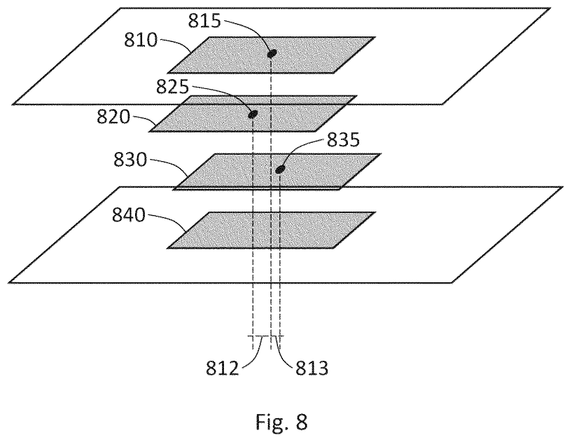

FIG. 8 is a diagram illustrating diagnosing an object by determining overlays at multiple process layers, according to an embodiment of the present disclosure.

Performing multilayer scans with an SEM system can facilitate identifying errors in a manufactured object, which may be present in locations other than those initially planned or requested for diagnosis. In one embodiment, image data can be obtained at multiple process layers with an SEM system having a number of detectors (e.g., any combination of SE, BSE, EF, etc.) and utilizing a number of landing energy levels. FIG. 8 illustrates such multilayer imaging by showing an example of four process layers (810, 820, 830, 840). As noted previously, SE detectors generally image higher depth level features than BSE detectors that generally image buried features at lower depth levels, and higher landing energy levels also result in obtaining deeper images than lower landing energy levels. The example in FIG. 8 represents an example of having first process layer 810 being imaged by an SE detector with a 5 keV landing energy, second process layer 820 by an SE detector with a 10 keV landing energy, third process layer 830 by a BSE detector with a 25 keV landing energy, and a fourth process layer 840 by a BSE detector with a 30 keV landing energy.

The method can then include generating metrology characteristics for any of the process layers from the image data. The method can also include determining a difference between any two of the process layers based on the metrology characteristics and providing an indication when the difference exceeds a difference threshold. As described in further detail below, a user may be interested in determining whether the overlay between the first and third process layers is within a permissible range. With the disclosed method, other overlays (e.g., between the first and second process layers) can be determined and monitored. If the difference is outside a threshold (e.g., 5 nm., etc.) the imaged object and/or location of the images on the object can be flagged for attention as possibly containing an unacceptable error.

As shown in the example of FIG. 8, in some embodiments the metrology characteristics can be pattern locations, and the difference can be the overlay 812 between a first pattern location 815 on a first process layer 810 and a second pattern location 825 on a second process layer 820. Similarly, overlay 813 can be determined between first process layer 810 and third process layer 830 having a third pattern location 835. In other embodiments, the metrology characteristics can be CDs for OPC metrology, and the difference can be a CD difference between a first process layer and a second process layer (here referring to any two process layers). In some embodiments, the metrology characteristics can be LERs for SEPE metrology, and the difference can be an LER difference between a first process layer and a second process layer. In yet other embodiments, the metrology characteristics can be EPEs for EPE metrology, and the difference can be an EPE difference between a first process layer and a second process layer. As with other embodiments herein, these method embodiments can have the detectors include any combination of detectors, for example, an SE detector and a BSE detector as described above. In other embodiments, the detectors can include an EF detector, with the method including obtaining the image data utilizing the EF detector at different energy filter levels.

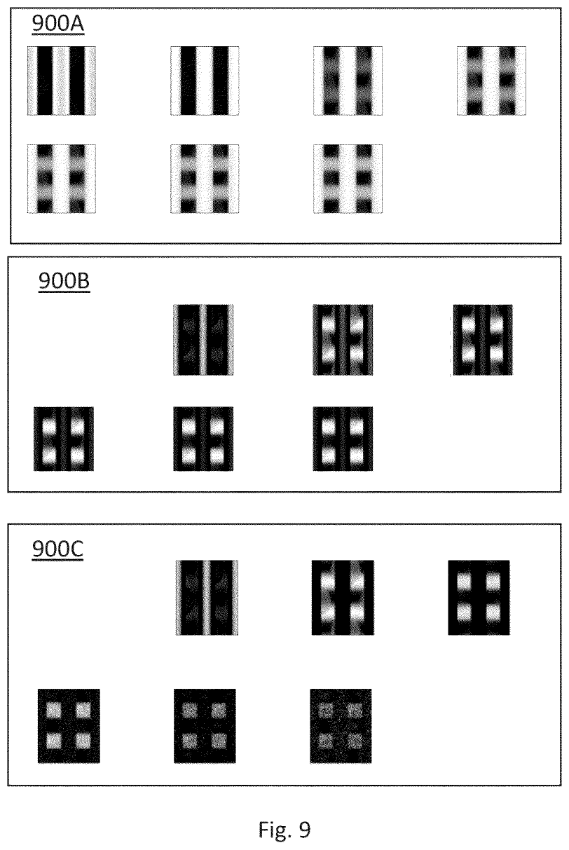

FIG. 9 is a diagram illustrating diagnosing process errors by utilizing composed images based on different landing energies, according to an embodiment of the present disclosure. Determining differences in manufactured objects or their features at varying depth levels can be utilized to determine if there were errors in manufacturing. For example, as previously discussed, knowing the locations of objects and/or patterns, images from different process layers can then be compared to the design layout to determine if any differences are within a permissible range. Imaging of particular process layers/depth levels can be performed by processing images (e.g., image subtraction) acquired at different landing energy levels. The images in panel 900A are examples of simulated images acquired at landing energies 1 keV (upper left), 5 keV, 10 keV, 15 keV, 20 keV, 25 keV, and 30 keV (lower right). It can be seen that information at different depth levels can be obtained by varying the landing energy. For example, at a 1 keV landing energy, the image represents very nearly only the surface of the object. As a landing energy increases, the electrons from the SEM penetrate further into the object and resultant scattered electrons contain information from deeper locations.

Panel 900 B shows examples of composed images where the 1 keV landing energy image in panel 900A has been subtracted from the other images (5, 10, 15, 20, and 25 keV landing energies). The upper left is then the 1 keV landing energy image subtracted from the 5 keV landing energy image. Here, without the dominant effect of the top process layer electron contributions, features at deeper levels can be seen more clearly, though due to the comparatively wide difference in landing energies (e.g., subtracting only top process layer image data) some intermediate depth level information remains.

Panel 900C depicts similar image differencing but over a narrower gap in landing energies. The images shown are from panel 900A but subtracting their nearest neighbors in landing energy. For example, the upper left image is from subtracting the 1 keV landing energy image from the 5 keV landing energy image. The next subtracts a 5 keV landing energy image from a 10 keV landing energy image, and so on to the lower left which subtracts a 25 keV landing energy image from a 30 keV landing energy image. Because the differencing is over a narrower range of landing energies, the unwanted contributions from shallower locations in the object are subtracted. The remaining image is then effectively localized at a particular depth level where information from the two landing energies are the dominant contributors. Thus, by performing particular differencing, combinations of landing energies can be used to effectively determine (or set) the depth level of imaging. Similar imaging can be utilized not just with different landing energies from the same type of detectors but also utilizing different combinations of detectors. In this way, some embodiments can include methods where particular combinations of detectors, landing energies, energy filter levels, etc. can be with appropriate differencing to localize the imaging to a particular depth level or process layer.

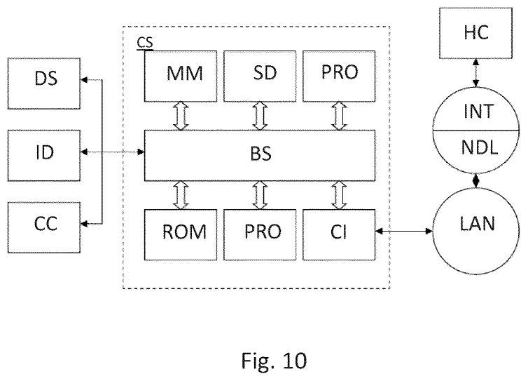

FIG. 10 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Embodiments of the present disclosure can be further described by the following clauses.
1. A method comprising:
   obtaining image data of an object with an SEM system, the image data acquired at multiple landing energy levels;
   generating a composed image by performing pixel-by-pixel image processing of the image data;
   determining a metrology characteristic from the composed image; and
   performing metrology on the feature based on the metrology characteristic.
2. The method of clause 1, wherein the feature is manufactured on a wafer through a semiconductor manufacturing process and the feature can include a contact hole, a short bar, a line, a tilted bar, a bit line, or an active area.
3. The method of clause 1, wherein the multiple landing energy levels are selected to obtain the image data from selected depth levels within the object.
4. The method of clause 1, wherein the metrology characteristic is a side wall angle of the feature.
5. The method of clause 1, wherein the metrology characteristic is a CD for OPC metrology.
6. The method of clause 1, wherein the metrology characteristic is a LER for SEPE metrology.
7. The method of clause 1, wherein the metrology characteristic is an EPE for EPE metrology.
8. The method of clause 1, wherein the metrology characteristic is an overlay for overlay metrology.
9. The method of clause 1, wherein the SEM system includes one or more BSE detectors that obtain first image data at a first landing energy and second image data at a second landing energy, the first landing energy being higher than the second landing energy.
10. The method of clause 8, wherein the composed image is generated by subtracting the second image data from the first image data.
11. The method of clause 1, wherein the SEM system includes a BSE detector and an EF detector, the BSE detector obtaining first image data at a first landing energy and the EF detector obtaining second image data at a second landing energy.
12. The method of clause 9, wherein the composed image is generated by subtracting the second image data from the first image data.
13. The method of clause 1, wherein the SEM system includes a BSE detector, an EF detector, and an SE detector, the BSE detector obtaining first image data at a first landing energy, the EF detector obtaining second image data at a second landing energy, and the SE detector obtaining third image data at a third landing energy.
14. The method of clause 10, wherein the composed image is generated by subtracting the second image data and the third image data from the first image data.
15. The method of clause 1, wherein the composed image is generated from function5(function1(BSE_1), function2(BSE_2), function3(SE), funcation4(EF)), wherein function1, function2, function 3, and function 4 are image pre-processing functions and function5 is a mathematical function that combines the image data processed by the image pre-processing functions.
16. The method of clause 11, wherein the image pre-processing functions are any combination of denoising functions or grey-level adjustments.
17. The method of clause 11, wherein the mathematical function is linear or non-linear function, including an addition, a subtraction, multiplication, division, Fourier analysis, or a logarithmic operation.
18. A method comprising:
   obtaining image data from multiple depth levels of an object from a first detector and a second detector of an SEM system;
   obtaining a first design layout corresponding to a first process layer of the object;
   obtaining a second design layout corresponding to a second process layer of the object;
   aligning the image data from the first detector with the first design layout;
   aligning the image data from the second detector with the second design layout; and
   determine a metrology characteristic from the aligned first image data and the aligned second image data.
19. The method of clause 18, wherein the first image data and the second image data are from the same location on the object.
20. The method of clause 18, wherein determining the metrology characteristic comprises calculating an overlay between the aligned first image data and the aligned second image data.
21. The method of clause 18, wherein the first design layout and the second design layout are comprised of GDS data.
22. The method of clause 18, wherein the first detector is an SE detector that generates first image data.
23. The method of clause 18, wherein the second detector is a BSE detector that generates second image data and the method further comprising generating third image data from an EF detector.
24. The method of clause 23, wherein the metrology characteristic is a pattern shift between the first process layer and the second process layer, determining the pattern shift comprising:
   determining a difference between a second location of the aligned second image data and a first location of the aligned first image data, the aligned second image data determined in part by subtracting the third image data from the second image data.
25. A method comprising:
   obtaining image data from multiple depth levels of an object from a first detector and a second detector of an SEM system;
   obtaining a design layout of the object;
   aligning the image data from the first detector with the design layout;
   determining a region of interest based on the aligned image data; and
   performing an image processing operation on the image data from the second detector in the region of interest.
26. The method of clause 25, the image processing operation comprising image quality enhancement.
27. The method of clause 25, the image processing operation comprising segmentation.
28. The method of clause 25, the image processing operation comprising contour extraction.
29. The method of clause 25, the image processing operation comprising template matching.
30. The method of clause 25, the image processing operation comprising machine learning based feature recognition.
31. A method comprising:
   obtaining image data of multiple depth levels of an object from a first detector and a second detector of an SEM system, the image data from the second detector being from a buried process layer of the object and one or more process layers above the buried process layer; and
   determining a metrology characteristic of a feature of the object based on the image data.
32. The method of clause 31, wherein the metrology characteristic is a side wall angle of the feature as determined from CDs as measured at the buried process layer and a second process layer and from a nominal thickness between the buried process layer and the second process layer, the side wall angle determined utilizing the first detector and the second detector or utilizing the first detector at different landing energies.
33. The method of clause 31, wherein the metrology characteristic includes LERs at multiple depth levels of the object.
34. The method of clause 31, wherein the metrology characteristic includes EPEs at multiple depth levels of the object.
35. The method of clause 31, wherein the first detector is an SE detector that generates first image data and the second detector is a BSE detector that generates second image data from the buried process layer.
36. A method comprising:
   obtaining image data of multiple process layers of an object from a plurality of detectors of an SEM system, the image data acquired at multiple landing energy levels for each of the plurality of detectors; and
   determining, from the image data of the multiple process layers, a combination of detectors and landing energies, current, scanning speed, pixel size and field of view size that result in a measured overlay being closest to directly proportional to a target overlay.
37. The method of clause 36, the method further comprising:
   setting, for the combination of detectors, the respective landing energies and other SEM parameters; and
   performing metrology utilizing the combination of detectors having the respective landing energies.
38. The method of clause 36, wherein the plurality of detectors includes an SE detector and a BSE detector.
39. The method of clause 36, wherein the plurality of detectors includes an EF detector, the method further comprising scanning multiple energy filter levels when obtaining the image data, wherein the combination also includes an energy filter level of the multiple energy filter levels.
40. The method of clause 36, further comprising generating composed images by combining at least a portion of the image data obtained by the scanning, the determining of the combination based on the combined image data.
41. A method comprising:
   obtaining image data at a plurality of process layers with an SEM system having a plurality of detectors utilizing a plurality of landing energy levels;
   generating a plurality of metrology characteristics for a plurality of process layers from the image data;
   determining a difference between two of the plurality of process layers based on the plurality of metrology characteristics; and
   providing an indication when the difference exceeds a difference threshold.
42. The method of clause 41, wherein the metrology characteristics are pattern locations and the difference is an overlay between a first pattern location on a first process layer and a second pattern location on a second process layer.
43. The method of clause 41, wherein the metrology characteristics are CDs for OPC metrology and the difference is a CD difference between a first process layer and a second process layer.
44. The method of clause 41, wherein the metrology characteristics are LERs for SEPE metrology and the difference is an LER difference between a first process layer and a second process layer.
45. The method of clause 41, wherein the metrology characteristics are EPEs for EPE metrology and the difference is an EPE difference between a first process layer and a second process layer.
46. The method of clause 41, wherein the plurality of detectors include an SE detector and a BSE detector.
47. The method of clause 41, wherein the plurality of detectors include an EF detector, the method further comprising obtaining the image data utilizing the EF detector at a plurality of energy filter levels.
48. A non-transitory computer readable medium having instructions recorded thereon for use with a lithographic process, the instructions when executed by a computer having at least one programmable processor cause operations comprising, the operations as in any of clauses 1-47.
49. A system for use with a lithographic process, the system comprising:
   at least one programmable processor; and
   a non-transitory computer readable medium having instructions recorded thereon, the instructions when executed by a computer having the at least one programmable processor cause operations as in any of clauses 1-47.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A method comprising:
obtaining image data of an object with a SEM system, the image data acquired at multiple landing energy levels;
generating a composed image by performing pixel-by-pixel image processing of the image data;
determining a metrology characteristic from the composed image; and
performing metrology on a feature based on the metrology characteristic, wherein the feature is manufactured on a wafer through a semiconductor manufacturing process.

2. The method of claim 1, wherein the multiple landing energy levels are selected to obtain the image data from selected depth levels within the object.

3. The method of claim 1, wherein the metrology characteristic is a side wall angle of the feature.

4. The method of claim 1, wherein the metrology characteristic is a critical dimension (CD) for optical proximity correction (OPC) metrology.

5. The method of claim 1, wherein the metrology characteristic is a line edge roughness (LER) for stochastic edge placement error (SEPE) metrology.

6. The method of claim 1, wherein the metrology characteristic is an edge placement error (EPE) for EPE metrology.

7. The method of claim 1, wherein the metrology characteristic is an overlay for overlay metrology.

8. The method of claim 1, wherein the SEM system includes one or more backscattered electrons (BSE) detectors that obtain first image data at a first landing energy and second image data at a second landing energy, the first landing energy being higher than the second landing energy, wherein the composed image is generated by subtracting the second image data from the first image data.

9. The method of claim 1, wherein the SEM system includes a backscattered electron (BSE) detector and an energy filter (EF) detector, the BSE detector obtaining first image data at a first landing energy and the EF detector obtaining second image data at a second landing energy, wherein the composed image is generated by subtracting the second image data from the first image data.

10. The method of claim 1, wherein the SEM system includes a backscattered electron (BSE) detector, an energy filter (EF) detector, and a scattered electron (SE) detector, the BSE detector obtaining first image data at a first landing energy, the EF detector obtaining second image data at a second landing energy, and the SE detector obtaining third image data at a third landing energy wherein the composed image is generated by subtracting the second image data and the third image data from the first image data.

11. The method of claim 1, wherein the composed image is generated from function5(function1(BSE_1), function2(BSE_2), function3(SE), funcation4(EF)), wherein function1, function2, function3, and function4 are image pre-processing functions and function5 is a mathematical function that combines the image data processed by the image pre-processing functions.

12. The method of claim 11, wherein the image pre-processing functions are any combination of denoising functions or grey-level adjustments.

13. The method of claim 11, wherein the mathematical function is a linear or non-linear function, including an addition, a subtraction, multiplication, division, Fourier analysis, or a logarithmic operation.

14. A non-transitory computer readable medium having recorded instructions for use with a lithographic process, the instructions, when executed by a computer system, configured to cause having at least one programmable processor to at least:
obtain image data of an object with a SEM system, the image data acquired at multiple landing energy levels;
generate a composed image by performing pixel-by-pixel image processing of the image data;
determine a metrology characteristic from the composed image; and
cause performance of metrology on a feature based on the metrology characteristic, wherein the feature is manufactured on a wafer through a semiconductor manufacturing process.

15. A system for use with a lithographic process, the system comprising:
at least one programmable processor; and
the non-transitory computer readable medium of claim 14.

16. The medium of claim 14, wherein the multiple landing energy levels are selected to obtain the image data from selected depth levels within the object.

17. The medium of claim 14, wherein the metrology characteristic is a side wall angle of the feature, a critical dimension (CD) for optical proximity correction (OPC) metrology, a line edge roughness (LER) for stochastic edge placement error (SEPE) metrology, an edge placement error (EPE) for EPE metrology, or an overlay for overlay metrology.

18. The medium of claim 14, wherein the SEM system includes one or more backscattered electrons (BSE) detectors that obtain first image data at a first landing energy and second image data at a second landing energy, the first landing energy being higher than the second landing energy, wherein the composed image is generated by subtraction of the second image data from the first image data.

19. The medium of claim 14, wherein the SEM system includes a backscattered electron (BSE) detector and an energy filter (EF) detector, the BSE detector obtaining first image data at a first landing energy and the EF detector obtaining second image data at a second landing energy, wherein the composed image is generated by subtraction of the second image data from the first image data.

20. The medium of claim 14, wherein the SEM system includes a backscattered electron (BSE) detector, an energy filter (EF) detector, and a scattered electron (SE) detector, the BSE detector obtaining first image data at a first landing energy, the EF detector obtaining second image data at a second landing energy, and the SE detector obtaining third image data at a third landing energy wherein the composed image is generated by subtraction of the second image data and the third image data from the first image data.
